(19) United States
(12) Patent Application Publication
(10) Pub. No.: US 2024/0331302 A1
(43) Pub. Date: Oct. 3, 2024

(54) SYSTEMATIC METHOD FOR GENERATING PLANAR EXPANDABLE STRUCTURE BY ADDING HINGED SURFACES BASED ON UNIFORM TESSELLATION

(71) Applicant: ZHEJIANG UNIVERSITY, Hangzhou (CN)

(72) Inventor: Hui Wang, Hangzhou (CN)

(21) Appl. No.: 18/737,901

(22) Filed: Jun. 7, 2024

Related U.S. Application Data
(63) Continuation of application No. PCT/CN2022/123870, filed on Oct. 8, 2022.

(30) Foreign Application Priority Data
Dec. 8, 2021 (CN) 202111491334.X

(51) Int. Cl. G06T 17/20; G06T 19/20

(52) U.S. Cl. CPC G06T 17/205; G06T 19/20; G06T 2219/2021

(57) ABSTRACT

The present disclosure discloses a systematic method for generating a planar expandable structure by adding hinged surfaces based on uniform tessellation, including: establishing a database of graphs which are in planar uniform tessellation; selecting one, inputting a graph of any desired size range, naming the graph as Graph A; drawing a dual tessellation graph of the Graph A, extracting a basic unit B of the dual tessellation graph; adjusting the length of each side of the basic unit B to obtain Ring B′; sequentially adding original regular polygons in the Graph A to angular points corresponding to the Ring B′; sequentially connecting vertices of each regular polygon inside the Ring B′ to constitute a new polygon C, and hinging with surrounding regular polygons at the vertex to obtain an expandable structural unit; spreading the expandable structural unit over a required range by means of offset, and outputting an overall structure.

### CROSS-REFERENCE TO RELATED APPLICATIONS

This application is a continuation of co-pending International Patent Application No. PCT/CN2022/123870, filed on Oct. 8, 2022, which claims the priority and benefit of Chinese patent application number 202111491334.X, filed on Dec. 8, 2021 with China National Intellectual Property Administration, the entire contents of which are incorporated herein by reference.

### TECHNICAL FIELD

The present application relates to the technical field of generating planar expandable structures, and in particular, to a systematic method for generating a planar expandable structure by adding hinged surfaces based on uniform tessellation.

### BACKGROUND

A movable structure is widely used in the fields of architecture and decoration design, mechanical design, stage design, product design and so on. At present, the common movable structures at home and abroad mostly adopt the way of three-dimensional folding or rotation, forming dynamic changes through the folding or rotation of each component in space. For example, in the movable building curtain wall or ceiling, the distributed drive mechanism is used to rotate a large number of small parts independently to obtain the overall opening and closing effect of the curtain wall.

In the process of implementing the present disclosure, the inventor found at least the following problems:

The three-dimensional movable manner usually occupies a large space, is complex in structure, requires many driving mechanisms, consumes much energy, is high in construction and operation costs and relatively low in stability, has limited design types, and is thus not universal and systematic.

### SUMMARY

In view of above issues, embodiments of the present application aim to provide a systematic method for generating a planar expandable structure by adding hinged surfaces based on uniform tessellation so as to overcome defects in the relevant technology.

According to an embodiment of the present application, provided is a systematic method for generating a planar expandable structure by adding hinged surfaces based on uniform tessellation, the method including the following steps:
establishing a database of graphs which are in planar uniform tessellation, the database of graphs which are in planar uniform tessellation including a plurality of tessellation modes;
selecting one of the tessellation modes, inputting a graph of any desired size range, and naming the graph as Graph A;
drawing a dual tessellation graph of the Graph A, and extracting a basic unit B of the dual tessellation graph;
adjusting the length of each side of the basic unit B to obtain Ring B′;
sequentially adding original regular polygons in the Graph A to angular points corresponding to the Ring B′;
sequentially connecting vertices of each regular polygon inside the Ring B′ to constitute a new polygon C, and hinging with surrounding regular polygons at the vertex to obtain an expandable structural unit; and
spreading the expandable structural unit over a required range by means of offset, and outputting an overall structure.

Further, the selecting one of the tessellation modes, inputting a graph of any desired size range, and naming the graph as Graph A, includes:
selecting one of the tessellation modes;
inputting corresponding parameters according to an expansion range of design and the number of units required;
if a range required for the design is approximately circular, then defining the number of units within a radius coverage; and
if the range required for the design is approximately rectangular, then defining the number of units in horizontal and vertical directions.

Further, the drawing a dual tessellation graph of the Graph A and extracting a basic unit B of the dual tessellation graph, includes:
connecting centroids of adjacent graphic units, with one centroid only being connected to centroids of two adjacent graphic units thereof,
the formed graph being the dual tessellation graph of the Graph A, and taking a smallest repeating unit in the dual tessellation graph and denoting same as the basic unit B.

Further, the adjusting the length of each side of the basic unit B to obtain Ring B′, includes:
keeping the direction of each side of the basic unit B constant, using equal ratio amplification with a ratio greater than 1, and forming a closed Ring B′ after adjusting the length.

Further, the sequentially adding original regular polygons in the Graph A to angular points corresponding to the Ring B′, includes:
extracting all original tessellation polygons corresponding to the basic unit B, denoting same in order as block 1, block 2 and block 3 . . . , and offsetting each block to the angular points corresponding to the Ring B′ with the centroid coinciding with the angular point.

Further, the spreading the expandable structural unit over a required range by means of offset, and outputting an overall structure, includes:
according to translational symmetry of the uniform tessellation, offsetting the obtained expandable structural unit, and spreading same over the required range to obtain a final planar expandable structure and output same.

A technical solution provided by the embodiment of the present application may have the following beneficial effects.

This method adopts a design idea of rotating and expanding in a planar direction, and obtains, according to a geometric tessellation principle and duality principle, the innovative and systematic method for generating a movable structure. The tessellation principle reveals all uniform tessellation modes composed of regular polygons, and the duality principle reveals a relative position relationship of the graph before and after displacement. This method uses the uniform tessellation as a prototype to generate the planar expandable structure, and is beneficial to overcome the current outstanding technical problems in movable design. (1) Three-dimensional rotation or folding occupies large space, is complex in structure, consumes much energy, is high in construction cost and relatively low in stability, and the like. (2) Design is only limited to a few types, and thus is not universal and systemic.

On the basis of the geometric uniform tessellation principle and duality principle, the embodiment of the present application provides the systematic method for generating a planar expandable structure by adding hinged surfaces based on uniform tessellation. By applying this method, planar expandable structures in many forms can be quickly generated. Facet components of each structure are simply hinged and linked, such that the structure can rotate and expand as a whole under a small driving force. Compared with a three-dimensional movable structure, the planar expandable structure has the characteristics of low cost, a small occupation thickness, a simple structure and strong stability, such that the structure has outstanding application advantages in practice.

The uniform tessellation composed of regular polygons is the most common geometric figure mode and is also most commonly used in all kinds of design work. This design method is used for generating the expandable structure based on uniform tessellation, which has good universality and practical application value. This method is suitable for most planar uniform tessellation patterns. Results can be used in the fields of architecture and decoration design, mechanical design, furniture design, industrial product design, dynamic logo design, material microstructure design and so on.

It should be understood that the above general description and the later detailed description are only exemplary and explanatory and cannot limit the present application.

### BRIEF DESCRIPTION OF THE DRAWINGS

Accompanying drawings herein are incorporated into a specification and constitute a part of this specification, show embodiments that conform to the present application, and are used for describing a principle of the present application together with this specification.

FIG. 1 is flowchart of a systematic method for generating a planar expandable structure by adding hinged surfaces based on uniform tessellation provided by an embodiment of the present disclosure;

FIG. 2 is a schematic diagram of 11 kinds of single-point of intersection one-order planar uniform tessellation graphs provided by the embodiment of the present disclosure;

FIG. 3 is a schematic diagram of a selected Graph A, a dual tessellation graph of the Graph A and a basic unit B of the dual tessellation graph provided by Embodiment 1 of the present disclosure;

FIG. 4 is a schematic diagram showing adding blocks to angular points corresponding to Graph B provided by Embodiment 1 of the present disclosure;

FIG. 5 is a schematic diagram of a closed state and a fully expanded state of a generated planar expandable structure provided by Embodiment 1 of the present disclosure;

FIG. 6 is a schematic diagram of a closed state and a fully expanded state of a planar expandable structure generated in a (3, 12, 12) tessellation mode provided by Embodiment 2 of the present disclosure; and

FIG. 7 is an effect picture of an expanded state and a closed state of generated movable building skin provided by Embodiment 2 of the present disclosure.

### DETAILED DESCRIPTION OF THE EMBODIMENTS

Exemplary embodiments will be described in detail herein, examples of which are represented in the accompanying drawings. When the following description relates to the accompanying drawings, the same numerals in different accompanying drawings indicate the same or similar elements, unless otherwise indicated. The modes of implementation described in the following exemplary embodiments do not represent all modes of implementation that are consistent with the present application. On the contrary, they are only examples of devices and methods that are consistent with some aspects of the present application, as described in detail in the appended claims.

Terms used in the present application are used solely for the purpose of describing particular embodiments and are not intended to limit the present application. Singular forms of “a,” “said,” and “the” as used in the present application and the appended claims are also intended to include plural forms, unless the context clearly indicates other meanings. It should also be understood that the term “and/or” as used herein refers to and includes any or all possible combinations of one or more of the listed items in association with each other.

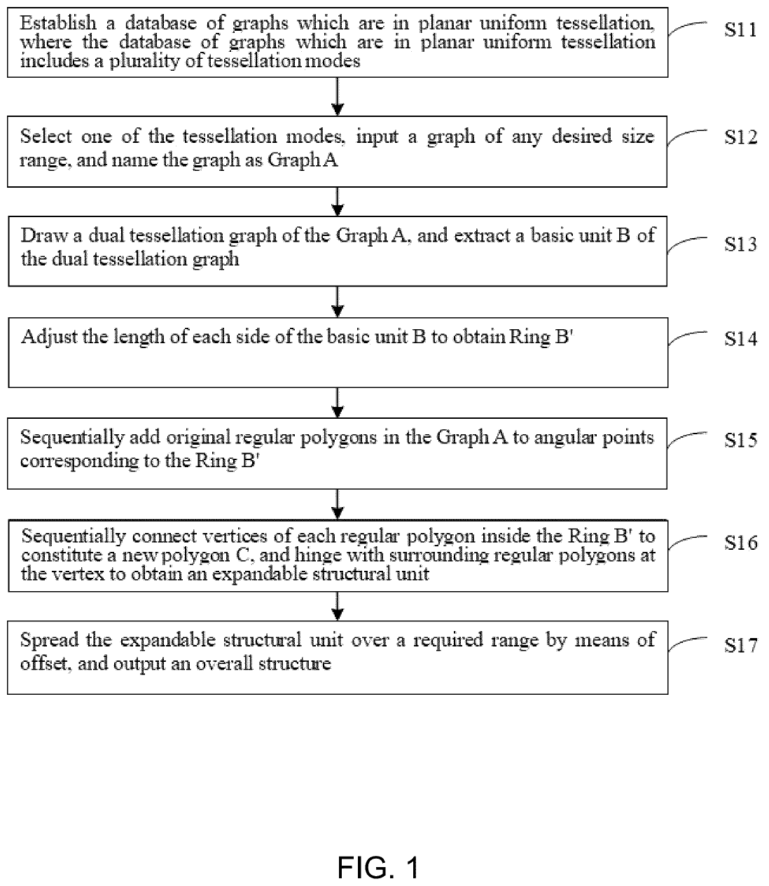

FIG. 1 is flowchart of a systematic method for generating a planar expandable structure by adding hinged surfaces based on uniform tessellation provided by an embodiment of the present disclosure. According to an embodiment of the present application, provided is a systematic method for generating a planar expandable structure by adding hinged surfaces based on uniform tessellation. The uniform tessellation composed of regular polygons is the most common combination mode of regular geometric figures and is also most commonly used in all kinds of design work. This method is based on a planar uniform tessellation pattern prototype, and establishes suitable tessellation graphic units and hinging manners thereof, so that the whole tessellation graph can rotate and expand on a plane. The method includes the following steps.

Step S11: establish a database of graphs which are in planar uniform tessellation, where the database of graphs which are in planar uniform tessellation includes a plurality of tessellation modes.

Specifically, input planar uniform tessellation modes and number same to obtain the database.

Step S12: select one of the tessellation modes, input a graph of any desired size range, and name the graph as Graph A.

Specifically, select one of the tessellation modes; input corresponding parameters according to an expansion range of design and the number of units required; if a range required for the design is approximately circular, then define the number of units within a radius coverage; and if the range required for the design is approximately rectangular, then define the number of units in horizontal and vertical directions.

Step S13: draw a dual tessellation graph of the Graph A, and extract a basic unit B of the dual tessellation graph.

Specifically, connect centroids of adjacent graphic units, with one centroid only being connected to centroids of two adjacent graphic units thereof, where the formed graph is the dual tessellation graph of the Graph A, and take a smallest repeating unit in the dual tessellation graph and denote same as the basic unit B.

Step S14: adjust the length of each side of the basic unit B to obtain Ring B′.

Specifically, keep the direction of each side of the basic unit B constant, use equal ratio amplification with a ratio greater than 1, and form a closed Ring B′ after adjusting the length.

Step S15: sequentially add original regular polygons in the Graph A to angular points corresponding to the Ring B′.

Specifically, extract all original tessellation polygons corresponding to the basic unit B, denote same in order as block 1, block 2 and block 3 . . . , and offset each block to the angular points corresponding to the Ring B′ with the centroid coinciding with the angular point.

Step S16: sequentially connect vertices of each regular polygon inside the Ring B′ to constitute a new polygon C, and hinge with surrounding regular polygons at the vertex to obtain an expandable structural unit.

Step S17: spread the expandable structural unit over a required range by means of offset, and output an overall structure.

Specifically, according to translational symmetry of the uniform tessellation, offset the obtained expandable structural unit, and spread same over the required range to obtain a final planar expandable structure and output same.

The above steps are further refined below in conjunction with embodiments.

### Embodiment 1

The present embodiment selects one graphic mode to generate a planar expandable structure based on the method provided by the present disclosure, which specifically includes the following steps:

Step 1: establish a database of graphs which are in planar uniform tessellation.

The planar tessellation refers to spreading geometric figures over a whole plane, without any gaps or overlaps between the figures. The planar tessellation studied by the present disclosure refers to side-to-side and point-to-point polygonal tessellation modes. If the tessellation is only composed of regular polygons, then it is called the uniform tessellation.

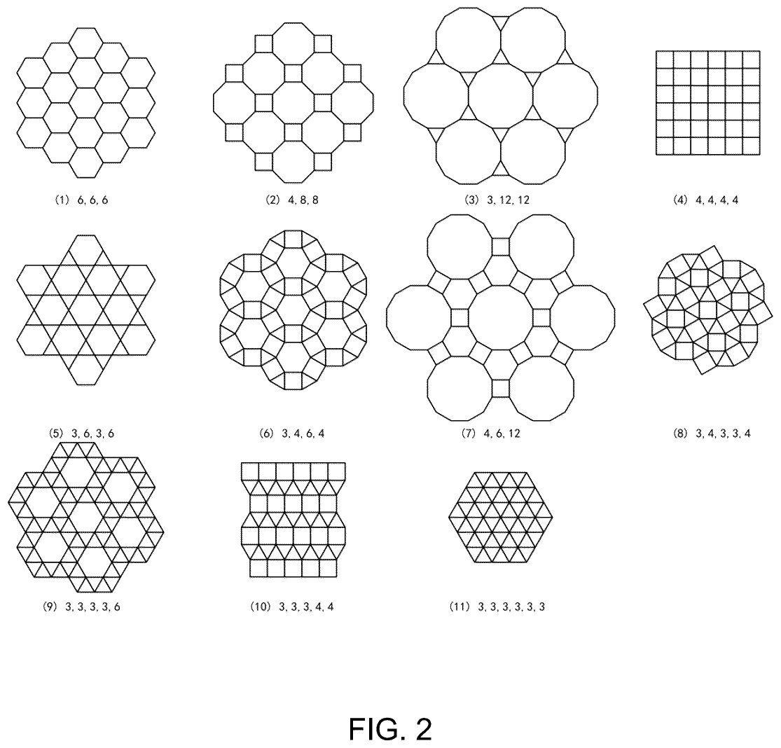

Take the single-point of intersection uniform tessellation (all points of intersection are in the same type) as an example, 11 kinds of planar tessellation modes are input, and a planar uniform tessellation database with code numbers of 1-11 is established, where numbers indicate the number of sides of regular polygons clustered at one point of intersection (Table 1). For convenient calculation, the lengths of sides of the tessellation polygons therein are all defined as 1, which can refer to FIG. 2.

TABLE 1
A database of single-point of intersection
one-order planar uniform tessellation

| | Tessellation polygon (numbers |
|---|---|
| Code | indicate the number of sides of the |
| number | regular polygon) |
| 1 | 6, 6, 6 |
| 2 | 4, 8, 8 |
| 3 | 3, 12, 12 |
| 4 | 4, 4, 4, 4 |
| 5 | 3, 6, 3, 6 |
| 6 | 3, 4, 6, 4 |
| 7 | 4, 6, 12 |
| 8 | 3, 4, 3, 3, 4 |
| 9 | 3, 3, 3, 3, 6 |
| 10 | 3, 3, 3, 4, 4 |
| 11 | 3, 3, 3, 3, 3, 3 |

Step 2: select one of the tessellation modes, input a graph of any desired size range, and name the graph as Graph A.

In the present embodiment, the sixth mode (3, 4, 6, 4) in Table 1 is selected as an demonstration.

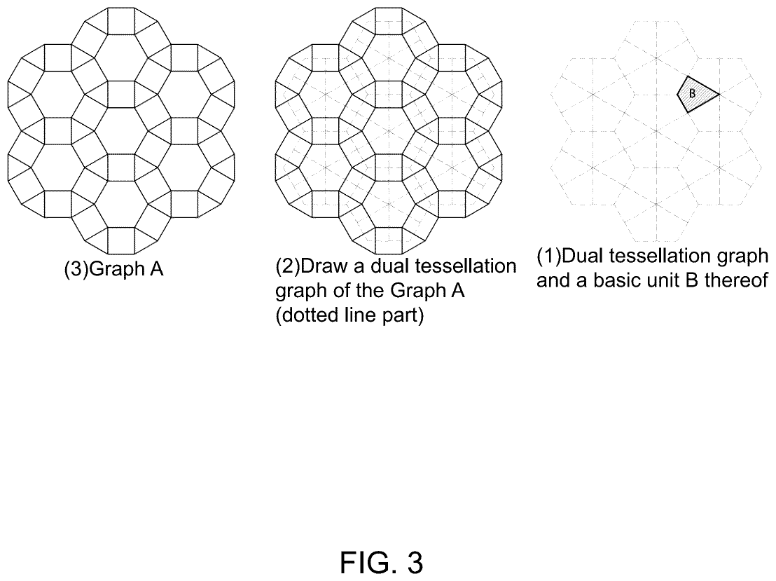

Input corresponding parameters according to an expansion range of design and the number of units required. If a range required for the design is approximately circular, then define the number of units within a radius coverage, and if the range required for the design is approximately rectangular, then define the number of units in horizontal and vertical directions. In the present embodiment, designing expandable skin is taken as an example, the input (3, 4, 6, 4) tessellation mode is in an approximate circular range, and the obtained Graph A is as shown in (1) in FIG. 3.

Step 3: draw a dual tessellation graph of the Graph A, and extract a basic unit B of the dual tessellation graph.

In the Graph A, take centroids of each regular triangle, square and regular hexagon and connect centroids of adjacent graphic units, with one centroid only being connected to the centroids of two adjacent graphic units thereof, where the formed graph is the dual tessellation graph of the Graph A, (a dotted line part of (2) in FIG. 3). Take a smallest repeating unit of the dual tessellation graph, which is an irregular quadrangle in the present embodiment, and denote same as the basic unit B ((3) in FIG. 3).

Step 4, adjust the length of each side of the basic unit B to obtain Ring B′.

Use an equal ratio amplification manner, where a ratio can be determined as required and is only required to be greater than 1. An amplified graph outer contour is the Ring B′.

Step 5: sequentially add original regular polygons in the Graph A to angular points corresponding to the Ring B′.

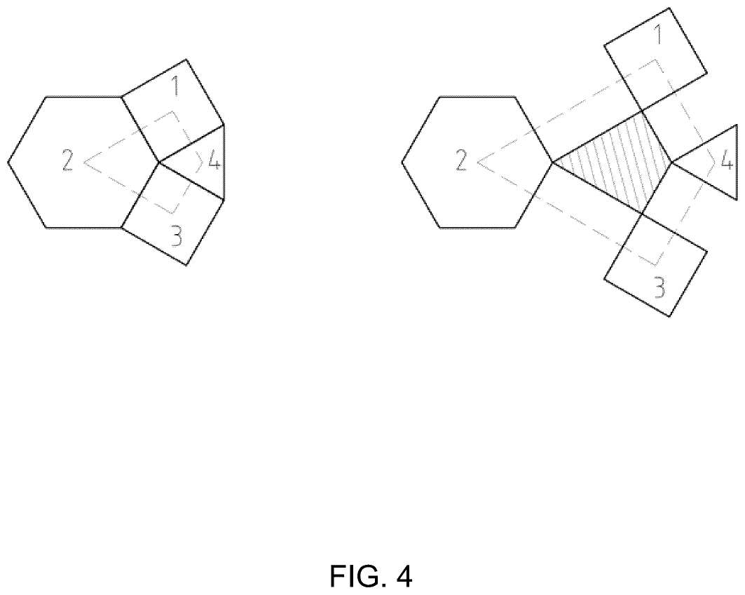

Extract original regular polygons of the Graph A, where in the present embodiment, there are one regular hexagon, one regular triangle and two squares, which are sequentially numbered from block 1 to block 4 ((1) in FIG. 4). Add the blocks 1, 2, 3 and 4 to the angular points corresponding to the Ring B′.

Step 6: sequentially connect vertices of each regular polygon inside the Ring B′ to constitute a new polygon C, and hinge with surrounding regular polygons at the vertex to obtain an expandable structural unit.

Sequentially connect vertices of the blocks from 1 to 4 inside the Ring B′ to constitute a new polygon C, and hinge with surrounding regular polygons at the vertex to obtain an expandable structural unit in hinged tessellation ((2) in FIG. 4).

Step 7: spread the expandable structural unit over a required range by means of offset, and output an overall structure.

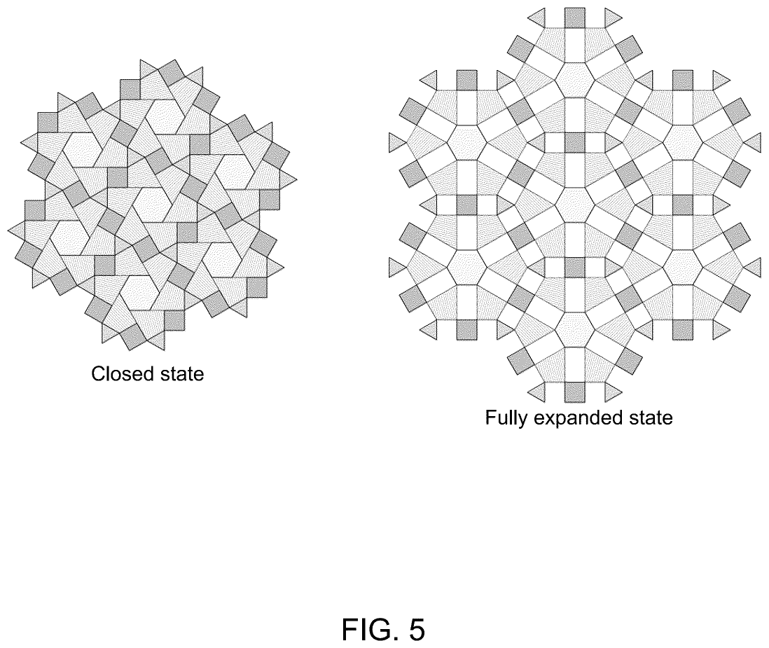

Offset the expandable structural unit to spread same over the required range, then obtain a fully expanded state of an expandable structure, and output an overall structure (FIG. 5). Since the hinged surfaces are added, a closed state thereof is different from that of an original tessellation mode, but a seamless and non-overlapping state can still be kept.

Output the overall structure, and count information such as the type, number and hinge joint number of the block.

The present embodiment shows uniform tessellation based on a (3, 4, 6, 4) type. By adding a quadrangle hinged surface, an example of a planar expandable structure is obtained. The expandable structure consists of 4 types of facets, which are hinged to each other. Both a closed state and an expanded state thereof are different from those of an original tessellation mode. The present embodiment has beautiful patterns, few component types and a simple structure, and can rotate and expand along a planar direction under the action of a single driving force to achieve a movable effect.

### Embodiment 2

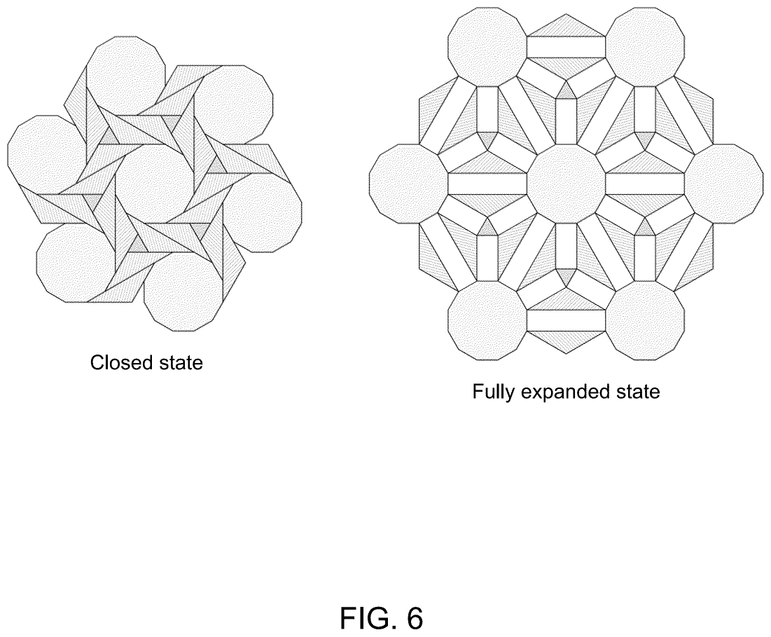

The present embodiment relates to a scheme for generating movable building skin based on the method provided by the present disclosure. In terms of the method, step 1 to step 6 are the same as those in Embodiment 1. In specific operations, a third tessellation mode (3, 12, 12) is selected in step 2, and forms of a generated planar expandable structure are as shown in FIG. 6.

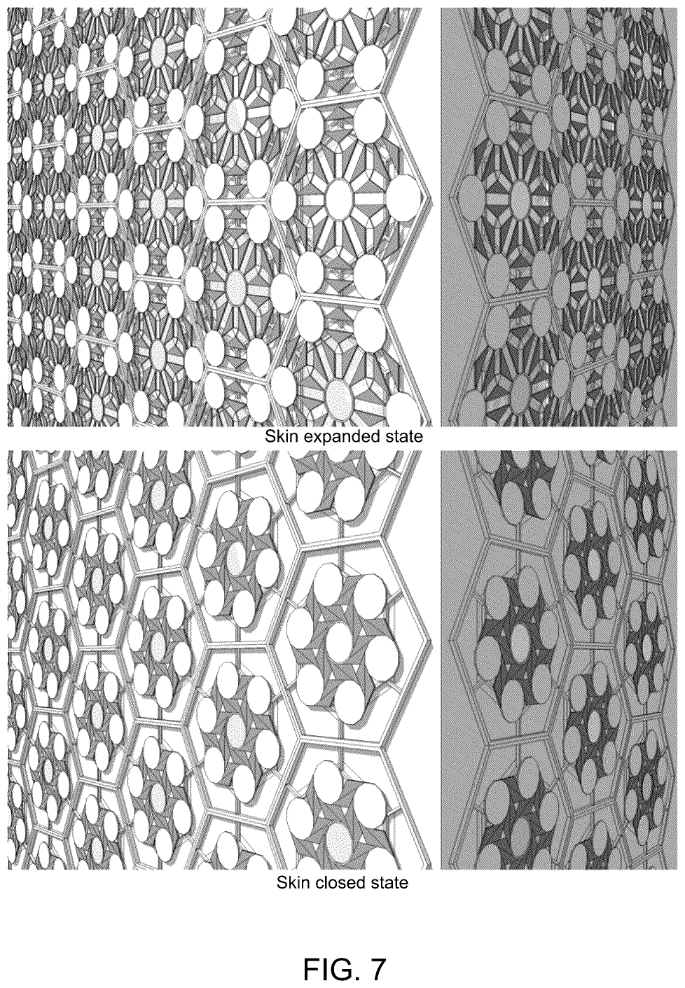

Step 7, adjust a scale as required, and output the overall structure. The specific practice: according to the size of a window of a building elevation, adjust the scale of the structural unit, and in the present embodiment, the length of sides of a polygonal unit is set to be 225 mm. Considering daylighting and ventilation requirements of a building, the skin in a closed state also has a certain degree of permeability, and a regular dodecagonal block at the center of the structural unit can be hollowed out. Generate an orthohexagonal outer contour of the structural unit as keels of the building skin, and add supports at appropriate positions inside to form a structural layer of the skin. Offset the structural unit to obtain a final building skin effect picture (FIG. 7).

Finally, output information about the type of facets of the building skin. In this movable skin, there are 3 types of facets, being a regular triangle, a regular dodecagon, and an isosceles triangle. Output the number of various components, which will be prefabricated in the factory for fabricated construction during actual construction.

This movable building skin has the advantages that the graphs themselves are highly decorative, with fewer types of components, which are simply hinged, and can rotate and expand along a planar direction under the action of a single driving force. It is also possible to adjust the skin to be opened or closed in combination with existing sensing and mechanical driving technologies according to the intensity of optical radiation to achieve an energy-saving effect of a building.

When the optical radiation is weak, the skin is in an expanded state to meet the demand of natural daylighting. When the optical radiation is strong, closed states in different degrees are used to shield direct irradiation of sunlight, thereby alleviating indoor glare and heat radiation.

The embodiments of the systematic method for generating a planar extendable structure by adding hinged surfaces based on uniform tessellation are described above. Generate the planar extendable structure based on the uniform tessellation mode, and add the hinged surface, such that the tessellated graph can rotate and expand on a plane. And output information such as the type, size and number of blocks required for fabrication.

The present disclosure provides a method for generating a planar expandable structure, which provides a systematic solution for innovative design of movable structural forms. This method can be applied to most planar uniform tessellation graphs revealed in the current geometry. The present disclosure is not limited to the above embodiments, and any technical solutions not departing from the present invention, i.e., merely carrying out improvements or changes known to a person of ordinary skill in the art thereon, are all within the scope of protection of the present disclosure.

Those skilled in the art can easily conceive of other implementation solutions of the present application upon consideration of the specification and practice of what is disclosed herein. The present application is intended to cover any variations, uses, or adaptive changes thereof, which follow the general principles of the present application and include common general knowledge or customary technical means in the technical field not disclosed herein. The specification and embodiments are to be regarded as exemplary only, and the true scope and spirit of the present application are indicated by the claims.

It is to be understood that the present application is not limited to the precise structure described above and illustrated in the accompanying drawings, and that various modifications and changes may be made without departing from the scope thereof. The scope of the present application is limited only by the appended claims.

What is claimed is:

1. A systematic method for generating a planar expandable structure by adding hinged surfaces based on uniform tessellation, wherein the method comprises the following steps:
establishing a database of graphs which are in planar uniform tessellation, the database of graphs which are in planar uniform tessellation comprising a plurality of tessellation modes;
selecting one of the tessellation modes, inputting a graph of any desired size range, and naming the graph as Graph A;
drawing a dual tessellation graph of the Graph A, and extracting a basic unit B of the dual tessellation graph;
adjusting the length of each side of the basic unit B to obtain Ring B′;
sequentially adding original regular polygons in the Graph A to angular points corresponding to the Ring B′;
sequentially connecting vertices of each regular polygon inside the Ring B′ to constitute a new polygon C, and hinging with surrounding regular polygons at the vertex to obtain an expandable structural unit; and
spreading the expandable structural unit over a required range by means of offset, and outputting an overall structure;
wherein the drawing a dual tessellation graph of the Graph A, and extracting a basic unit B of the dual tessellation graph, comprises:
connecting centroids of adjacent graphic units, with one centroid only being connected to centroids of two adjacent graphic units thereof, the formed graph being the dual tessellation graph of the Graph A, and taking a smallest repeating unit in the dual tessellation graph and denoting same as the basic unit B.

2. The method according to claim 1, wherein the establishing a database of graphs which are in planar uniform tessellation, comprises:
inputting planar uniform tessellation modes and numbering same to obtain the database.

3. The method according to claim 1, wherein the selecting one of the tessellation modes, inputting a graph of any desired size range, and naming the graph as Graph A, comprises:
selecting one of the tessellation modes;
inputting corresponding parameters according to an expansion range of design and the number of units required;
if a range required for the design is approximately circular, then defining the number of units within a radius coverage; and
if the range required for the design is approximately rectangular, then defining the number of units in horizontal and vertical directions.

4. The method according to claim 1, wherein the adjusting the length of each side of the basic unit B to obtain Ring B′, comprises:
keeping the direction of each side of the basic unit B constant, using equal ratio amplification with a ratio greater than 1, and forming a closed Ring B′ after adjusting the length.

5. The method according to claim 1, wherein the sequentially adding original regular polygons in the Graph A to angular points corresponding to the Ring B′, comprises:
extracting all original tessellation polygons corresponding to the basic unit B, denoting same in order as block 1, block 2 and block 3 . . . , and offsetting each block to the angular point corresponding to the Ring B′ with the centroid coinciding with the angular point.

6. The method according to claim 1, wherein the spreading the expandable structural unit over a required range by means of offset, and outputting an overall structure, comprises:
according to translational symmetry of the uniform tessellation, offsetting the obtained expandable structural unit, and spreading same over the required range to obtain a final planar expandable structure and output same.
